(19) United States
(12) Patent Application Publication
(10) Pub. No.: US 2013/0277515 A1
(43) Pub. Date: Oct. 24, 2013

(54) HARD DISK BRACKET

(71) Applicants: Yung-Tai Pan, Taipei (TW); Shang-Hao Su, Taipei (TW)

(72) Inventors: Yung-Tai Pan, Taipei (TW); Shang-Hao Su, Taipei (TW)

(73) Assignee: PRIMAX ELECTRONICS LTD., Taipei (TW)

(21) Appl. No.: 13/554,758

(22) Filed: Jul. 20, 2012

(30) Foreign Application Priority Data
Apr. 20, 2012 (TW) 101114170

(51) Int. Cl. H05K 7/14

(52) U.S. Cl. 248/224.8; 248/225.21

(57) ABSTRACT

A hard disc bracket is provided for fixing a hard disc within a computer case. The hard disc bracket includes frame body, a frame lateral plate, a receiving space, and at least one hook. The receiving space is defined by the frame body and the frame lateral plate collaboratively. The at least one hook is located at an upper edge of the frame lateral plate. When the hard disc is accommodated within the receiving space, the at least one hook is engaged with the hard disc to fix the hard disc on the frame body. Consequently, the hard disc may be fixed on the hard disc bracket without the need of using a screwdriver or any other tool.

### FIELD OF THE INVENTION

The present invention relates to a bracket, and more particularly to a hard disc bracket for fixing a hard disc within a computer case.

### BACKGROUND OF THE INVENTION

With rapid development of electronic and information industries, computers and the peripheral device thereof become essential parts in our daily lives. In addition to the working purposes, computers can be employed as amusement tools. Generally, a computer comprises a display screen, a computer case, a motherboard, a hard disc, a microprocessor, a memory, and other components. Recently, the manufacturers of the computers pay much attention to these components and try to improve the outward appearance, performance and use lives of these components. In these components of the computer, the microprocessor and the memory are mounted on the motherboard, and the hard disc is fixed on the computer case.

Conventionally, the hard disc is directly fixed on the computer case by screwing means. For facilitating the user to remove the hard disc from the computer case, the hard disc may be firstly supported on a hard disc bracket, and then the hard disc bracket is stored within the computer case. In addition, the hard disc bracket is detachably connected to the computer case. By means of the hard disc bracket, the hard disc can be removed from the computer case or stored within the computer case more easily.

Hereinafter, the structure of a conventional hard disc bracket and a computer case will be illustrated with reference to FIG. 1. FIG. 1 is a schematic perspective view illustrating the relationship between a hard disc bracket and a computer case according to the prior art. In FIG. 1, a hard disc bracket 1 and a computer case 2 are shown. The hard disc bracket 1 is used for accommodating a hard disc (not shown). In addition, the hard disc bracket 1 may be stored within the computer case 2. The hard disc bracket 1 comprises two lateral plates 10, a receiving space 11, and two locking elements 12. The receiving space 11 is used for accommodating the hard disc. After the hard disc is accommodated within the receiving space 11, the hard disc is fixed on the hard disc bracket 1 by screwing means. The computer case 2 comprises two sliding tracks 20 and two openings 21. The two sliding tracks 20 are located at two sides of the computer case 2. Since the two lateral plates 10 of the hard disc bracket 1 may be respectively slid along the two sliding tracks 20, the sliding tracks 20 can facilitate storing the hard disc bracket 1 within the computer case 2. The two openings 21 are located at first ends of the two sliding tracks 20, respectively.

A process of fixing the hard disc on the computer case 2 will be illustrated as follows. Firstly, the hard disc is accommodated within the receiving space 11 of the hard disc bracket 1. Then, the hard disc is fixed within the receiving space 11 by a plurality of screws (not shown). Then, the two lateral plates 10 of the hard disc bracket 1 are respectively aligned with the two sliding tracks 20 of the computer case 2, and the hard disc bracket 1 is pushed to be slid into the computer case 2 along the two sliding tracks 20. Then, the two locking elements 12 are rotated to have the first ends 121 of the locking elements 12 insert into corresponding openings 21 of the computer case 2. Consequently, the hard disc bracket 1 is in a locked state. Under this circumstance, the hard disc bracket 1 is fixed on the computer case 2.

On the other hand, a process of removing the hard disc from the computer case 2 will be illustrated as follows. Firstly, the two locking elements 12 are rotated to have the first ends 121 of the locking elements 12 detach from corresponding openings 21 of the computer case 2. Consequently, the operating state of the hard disc bracket 1 is switched from the locked state to a released state. Then, by pulling the two locking elements 12 in the direction distant from the computer case 2, the hard disc bracket 1 is removed from the computer case 2. Afterwards, a screwdriver or another tool is employed to loosen the screws, and thus the hard disc may be removed from the hard disc bracket 1.

From the above discussions, the conventional hard disc bracket 1 can be used to accommodate the hard disc. In addition, due to the structure of the conventional hard disc bracket 1, the hard disc bracket 1 with the hard disc may be directly stored within the computer case 2 or the hard disc bracket 1 with the hard disc may be removed from the computer case 2 without the need of using a screwdriver or any other tool to disassemble the hard disc from the computer case 2. However, when the user wants to remove the hard disc from the conventional hard disc bracket 1, the screwdriver or any other tool is required to loosen the screws in order to remove the hard disc.

Therefore, there is a need of providing an improved hard disc bracket, in which the hard disc is disassembled from or combined with the hard disc bracket without the need of using a screwdriver or any other tool.

### SUMMARY OF THE INVENTION

The present invention provides a hard disc bracket, in which the hard disc is disassembled from or combined with the hard disc bracket without the need of using a screwdriver or any other tool.

In accordance with an aspect of the present invention, there is provided a hard disc bracket for fixing a hard disc within a computer case. The hard disc bracket includes a frame body, at least one frame lateral plate, a receiving space, and at least one hook. The at least one frame lateral plate is located at a first side of the frame body for stopping the hard disc from being escaped from the frame body. The receiving space is used for accommodating the hard disc, wherein the receiving space is defined by a bottom part of the frame body and the at least one frame lateral plate collaboratively. The at least one hook is located at an upper edge of the at least one frame lateral plate and extended from the upper edge of the at least one frame lateral plate in a direction toward the receiving space, wherein when the hard disc is accommodated within the receiving space, the hook is engaged with the hard disc to fix the hard disc on the frame body.

In an embodiment, the hard disc bracket further includes at least one protrusion. The at least one protrusion is located at the first side of the frame body. The hard disc has at one perforation corresponding to the at least one protrusion. The at least one perforation is disposed in a bottom surface of the hard disc and located at a side of the hard disc. When the hard disc is accommodated within the receiving space, the at least one protrusion is inserted into the at one perforation, so that the hard disc is fixed within the receiving space.

In an embodiment, the at least one protrusion is located at the first side of the frame body, and has a foolproof function. When a front end of the hard disc faces a first end of the frame body, the hard disc is permitted to be accommodated within the receiving space, and the at least one protrusion is permitted to be aligned with the at least one perforation and inserted into the at least one perforation.

In an embodiment, the at least one protrusion is extended from the bottom part of the frame body in a direction toward the receiving space. The at least one protrusion is perpendicular to the bottom part of the frame body. In addition, the at least one protrusion is integrally formed with the frame body.

In an embodiment, the hard disc bracket further includes a positioning wall, which is located at a first end of the frame body and connected with the at least one frame lateral plate. The positioning wall has at least one positioning rib, which is disposed on an inner surface of the positioning wall. When the hard disc is accommodated within the receiving space, the hard disc is stopped by the at least one positioning rib from being slid relative to the main frame.

In an embodiment, the at least one positioning rib is extended from the positioning wall in a direction toward the receiving space. The at least one positioning rib is integrally formed with the positioning wall. The positioning wall is perpendicular to the at least one frame lateral plate. In addition, the positioning wall and the at least one frame lateral plate are integrally formed with the frame body.

In an embodiment, the receiving space is defined by the bottom part of the frame body, the at least one frame lateral plate and the positioning wall collaboratively.

In an embodiment, the hard disc bracket further comprises at least one stopper, which is located at a second end of the frame body and connected with the at least one frame lateral plate. When the hard disc is accommodated within the receiving space, the hard disc is stopped by the stopper from being slid relative to the frame body.

In an embodiment, the at least one stopper is perpendicular to the at least one frame lateral plate, the at least one stopper is integrally formed with the at least one frame lateral plate, and the at least one frame lateral plate is integrally formed with the frame body.

In an embodiment, the computer case includes an entrance/exit and a plurality of resilience sheets. The entrance/exit is located at an end of the computer case. The main frame of the hard disc bracket is permitted to be introduced into the computer case through the entrance/exit. The resilience sheets are located at bilateral sides of the computer case. When the frame is stored within the computer case, the plurality of resilience sheets are sustained against the frame, thereby avoiding detachment of the frame from the computer case.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the relationship between a hard disc bracket and a computer case according to the prior art;

FIG. 2 is a schematic perspective view illustrating the relationship between a hard disc bracket, a hard disc and a computer case according to an embodiment of the present invention;

FIG. 3 is a schematic perspective view illustrating the relationship between a hard disc bracket and a hard disc according to an embodiment of the present invention;

FIG. 4 is a schematic perspective view illustrating the relationship between the hard disc bracket and the hard disc as shown in FIG. 3 and taken along another viewpoint;

FIG. 5 is a schematic cutaway view illustrating the combination of the hard disc and the hard disc bracket as shown in FIG. 2 and taken along the line A-A′;

FIG. 6 is a schematic cutaway view illustrating the combination of the hard disc and the hard disc bracket as shown in FIG. 2 and taken along the line B-B′; and

FIG. 7 is a schematic assembled view illustrating that the hard disc is accommodated within the hard disc bracket according to an embodiment of the present invention.

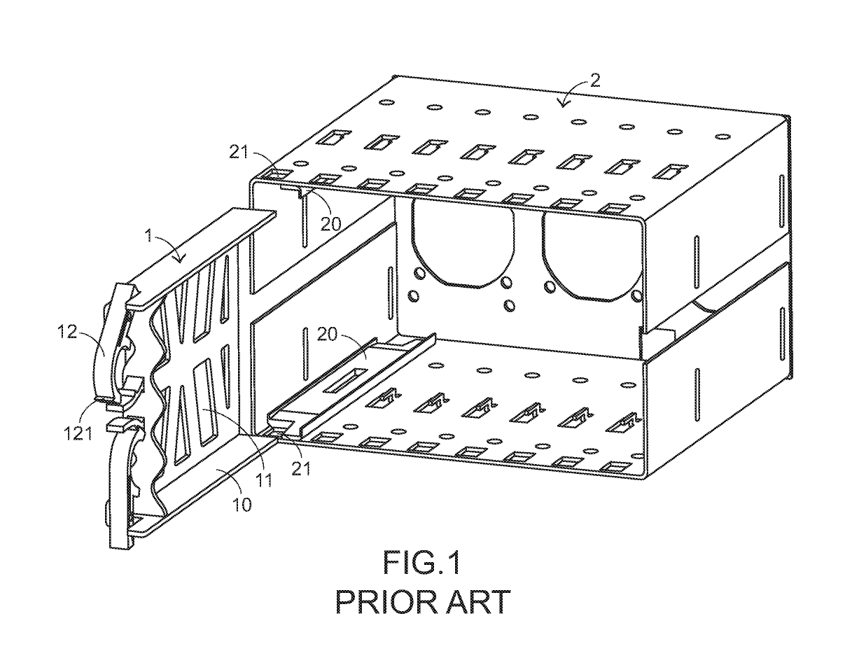

### DETAILED DESCRIPTION OF THE PREFERRED EMBODIMENT

For obviating the drawbacks encountered from the prior art, the present invention provides a hard disc bracket.

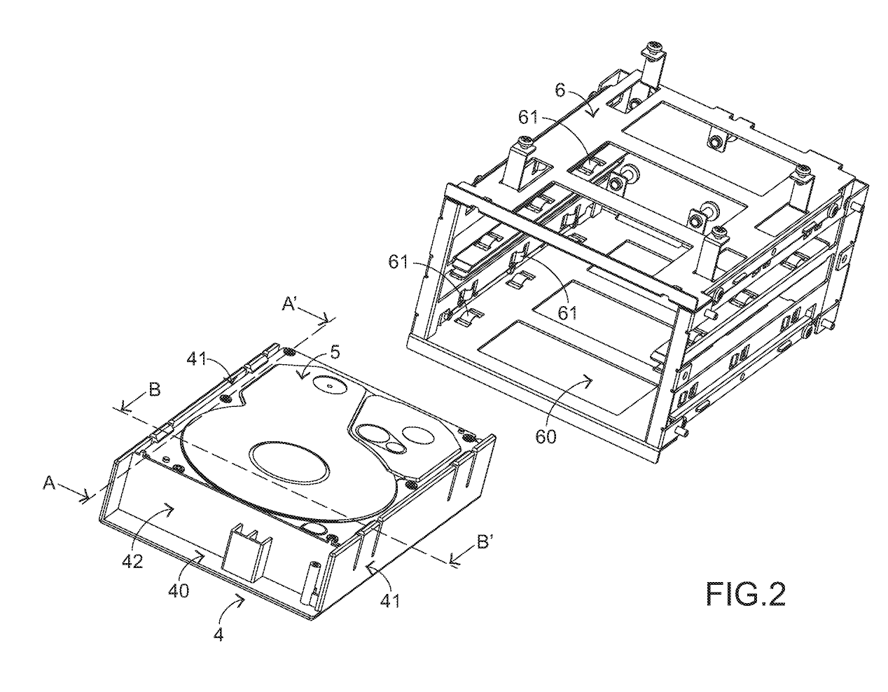

FIG. 2 is a schematic perspective view illustrating the relationship between a hard disc bracket, a hard disc and a computer case according to an embodiment of the present invention. In FIG. 2, a hard disc bracket 4, a hard disc 5 and a computer case 6 are shown. The hard disc bracket 4 comprises a frame body 40, two frame lateral plates 41, and a positioning wall 42. The frame body 40 is used for supporting the hard disc 5. In addition, the frame body 40 may be accommodated within the computer case 6. In this embodiment, the hard disc 5 is a 3.5-inch hard disc. As shown in FIG. 2, the computer case 6 comprises an entrance/exit 60 and a plurality of resilience sheets 61. The entrance/exit 60 is located at a front end of the computer case 6. Through the entrance/exit 60, the hard disc bracket 4 may be introduced into the computer case 6. The resilience sheets 61 are disposed within the computer case 6, and located at the bilateral sides of the computer case 6. After the main frame body 40 is stored within the computer case 6, the resilience sheets 61 are sustained against the main frame body 40 in order to avoid detachment of the main frame body 40 from the computer case 6.

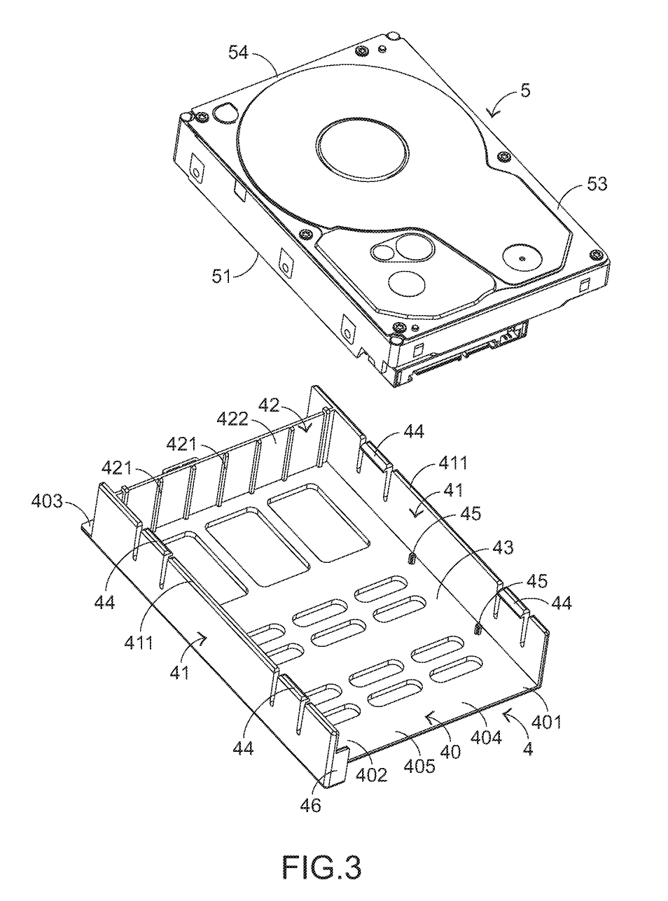

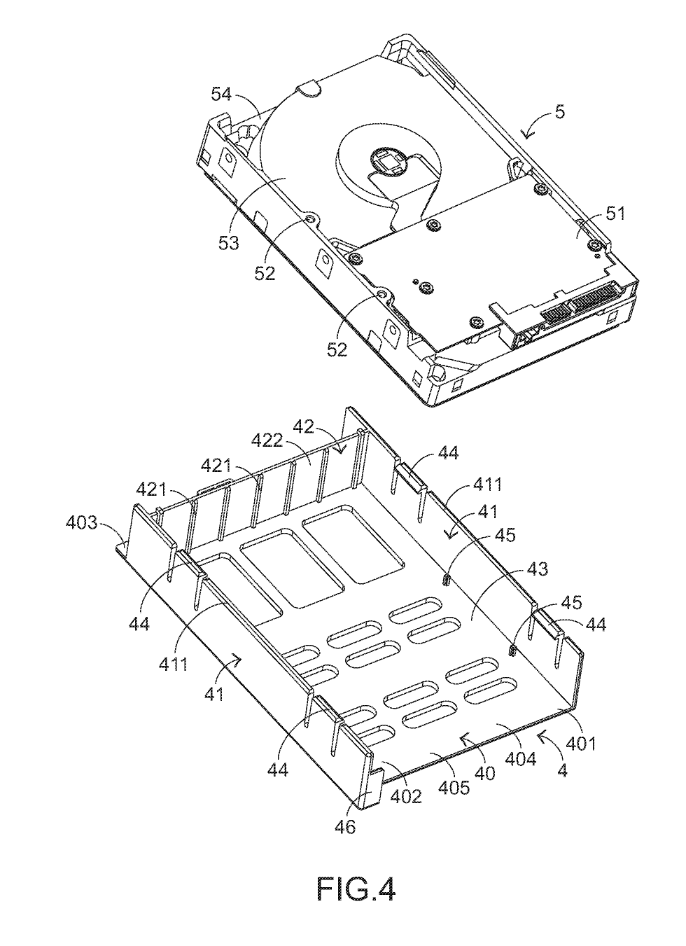

Hereinafter, the structures of the hard disc bracket will be illustrated with reference to FIGS. 3 and 4. FIG. 3 is a schematic perspective view illustrating the relationship between a hard disc bracket and a hard disc according to an embodiment of the present invention. FIG. 4 is a schematic perspective view illustrating the relationship between the hard disc bracket and the hard disc as shown in FIG. 3 and taken along another viewpoint. In addition to the frame body 40, the two frame lateral plates 41 and the positioning wall 42, the hard disc bracket 4 further comprises a receiving space 43, a plurality of hooks 44, two protrusions 45, and a stopper 46. The two frame lateral plates 41 are located at a first side 401 and a second side 402 of the frame body 40 for avoiding detachment of the hard disc 5 from the frame body 40. The positioning wall 42 is located at a first end 403 of the frame body 40, and arranged between the two frame lateral plates 41. Moreover, the positioning wall 42 is perpendicular to the two frame lateral plates 41, and connected with the two frame lateral plates 41. In addition, the positioning wall 42 has a plurality of positioning ribs 421. These positioning ribs 421 are formed on an inner surface 422 of the positioning wall 42. In this embodiment, the positioning wall 42 and the two frame lateral plates 41 are integrally formed with the frame body 40. Moreover, the frame body 40, the two frame lateral plates 41 and the positioning wall 42 are made of plastic material.

In the hard disc bracket 4, the receiving space 43 is defined by a bottom part 404 of the frame body 40, the two frame lateral plates 41 and the positioning wall 42 collaboratively. The receiving space 43 is used for accommodating the hard disc 5. These hooks 44 are located at the upper edges 411 of the frame lateral plates 41. In addition, the hooks 44 are extended from the upper edges 411 of the frame lateral plates 41 in the direction toward the receiving space 43. In this embodiment as shown in FIG. 3, two hooks 44 are located at the upper edge 411 of each frame lateral plate 41. After the hard disc 5 is accommodated within the receiving space 43, the top peripheries of the hard disc 5 are confined by the hooks 44. Consequently, the hard disc 5 can be securely fixed on the frame body 40. In this embodiment, these hooks 44 are integrally formed with the frame lateral plates 41. Moreover, since the hooks 44 are made of the same plastic material as the frame lateral plates 41, the hooks 44 have flexibility. Due to the flexibility, theses hooks 44 may be slightly and externally bent in response to an external force without being broken. Of course, the positioning wall 42 also has flexibility.

As shown in FIG. 3, two protrusions 45 are located at a side of the frame body 40. These two protrusions 45 are extended from the bottom part 404 of the frame body 40 in the direction toward the receiving space 43. In addition, these two protrusions 45 are perpendicular to the bottom part 404 of the frame body 40. In FIG. 4, a bottom surface 51 of the hard disc 5 is shown. The hard disc 5 has two perforations 52. The two perforations 52 are disposed in the bottom surface 51 of the hard disc 5 and located at a first side 53 of the hard disc 5. The locations of the two perforations 52 correspond to the protrusions 45 of the hard disc bracket 4. In addition, the two protrusions 45 are inserted into the corresponding perforations 52 of the hard disc 5 for assisting in fixing the hard disc 5 within the receiving space 43 of the frame body 40, so that the hard disc 5 is not slid relative to the frame body 40. In this embodiment, the two protrusions 45 are disposed on the frame body 40, and the two protrusions 45 are integrally formed with the frame body 40. It is noted that the number of the protrusions 45 may be varied according to the practical requirements. For example, in some embodiments, one or more than two protrusions are disposed on the frame body.

Moreover, the two protrusions 45 are located at the first side 401 of the frame body 40, and the two corresponding perforations 52 are located at the first side 53 of the hard disc 5. For accommodating the hard disc 5 within the receiving space 43, the front end 54 of the hard disc 5 should be aligned with the first end 403 of the frame body 40 to have the protrusions 45 and the corresponding perforations 52 align with each other. On the other hand, if the front end 54 of the hard disc 5 is aligned with the second end 405 of the frame body 40, the two protrusions 45 fail to be inserted into the corresponding perforations 52 of the hard disc 5. Under this circumstance, the hard disc 5 fails to be accommodated within the receiving space 43. In other words, the two positioning posts 45 are inserted into the corresponding perforations 52 of the hard disc 5 in a foolproof manner.

The stopper 46 is located at the second end 405 of the frame body 40. In addition, the stopper 46 is perpendicular to the frame lateral plates 41, and connected to one of the frame lateral plates 41. When the hard disc 5 is accommodated within the receiving space 43, the stopper 46 is in contact with the hard disc 5 in order to stop the hard disc 5 from being slid in the horizontal direction. In this embodiment, the stopper 46 is integrally formed with one of the frame lateral plates 41. Moreover, the positioning ribs 421 of the positioning wall 42 are extended from the positioning wall 42 in the direction toward the receiving space 43. When the hard disc 5 is accommodated within the receiving space 43, the positioning ribs 421 are in contact with the hard disc 5 in order to stop the hard disc 5 from being slid in the horizontal direction. In this embodiment, the frame lateral plates 41 are integrally formed with the positioning wall 42.

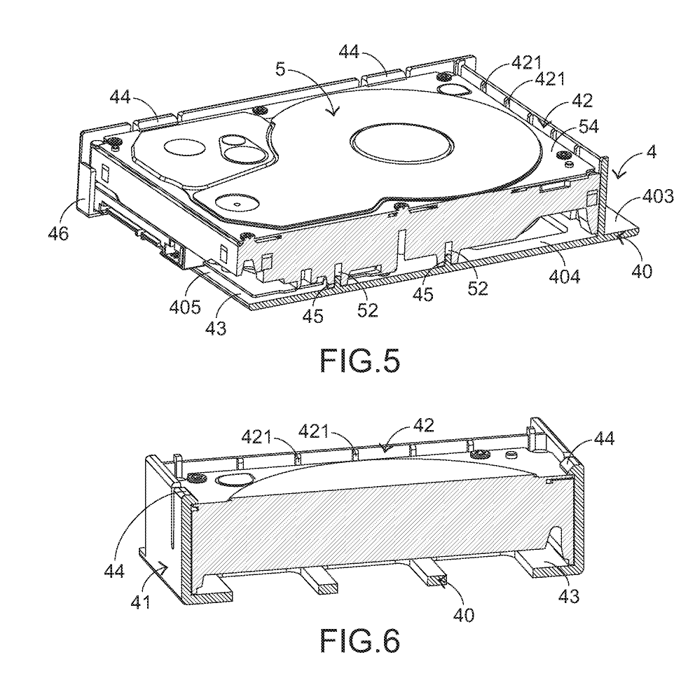

A process of accommodating and fixing the hard disc 5 within the receiving space 43 of the hard disc bracket 4 will be illustrated as follows. Please refer to FIG. 3. Firstly, the hard disc 5 is moved to a region over the receiving space 43 of the frame body 40, wherein the front end 54 of the hard disc 5 faces the first end 403 of the frame body 40 and the two perforations 52 of the hard disc 5 are aligned with the corresponding protrusions 45 of the hard disc bracket 4. After the two perforations 52 of the hard disc 5 are aligned with the corresponding protrusions 45 of the hard disc bracket 4, the hooks 44 are slightly and externally bent in response to an external force. Consequently, these hooks 44 are subject to slight deformation without being broken. Moreover, due to the slight deformation of the hooks 44, the positioning wall 42 is also subject to slight deformation. Under this circumstance, the cross-section area of the receiving space 43 is slightly increased to facilitate accommodating the hard disc 5 within the receiving space 43. After the hard disc 5 is accommodated within the receiving space 43, the two protrusions 45 of the hard disc bracket 4 are inserted into corresponding perforations 52 of the hard disc 5 (see FIG. 5). Meanwhile, the hard disc 5 is securely fixed within the receiving space 43 without being rocked or moved.

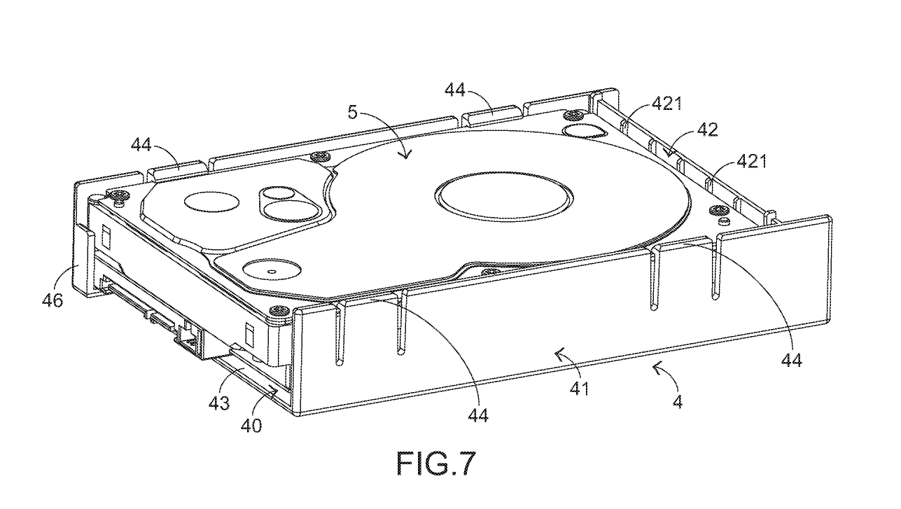

After the hard disc 5 is accommodated within the receiving space 43, the stopper 46 at the second end 405 of the frame body 40 is in contact with the hard disc 5 in order to assist in securely fixing the hard disc 5. Then, the external force exerted on the hooks 44 is eliminated, so that the hooks 44 are moved toward the receiving space and restored to the original states. After the hooks 44 are restored to the original states, the top peripheries of the hard disc 5 are confined by the hooks 44. Consequently, the hard disc 5 can be securely fixed on the frame body 40 without being escaped from the frame body 40 in the vertical direction (see FIG. 6). Moreover, after the external force exerted on the hooks 44 is eliminated, the deformation of the positioning wall 42 is recovered. Consequently, the ribs 421 of the positioning wall 42 are moved toward the receiving space 43, and then restored to the original states. Meanwhile, the ribs 421 are in contact with the hard disc 5 within the receiving space 43, so that the hard disc 5 is stopped from being slid relative to the frame body 40. After the hard disc 5 is accommodated within the receiving space 43 of the hard disc bracket 4, the resulting structure is shown in FIG. 7.

From the above description, the present invention provides a hard disc bracket. Since the hooks are engaged with the top peripheries of the hard disc, the hard disc can be securely fixed within the receiving space. Moreover, the uses of the protrusions, the positioning rib and the stopper can assist in fixing the hard disc within the receiving space. Consequently, the hard disc may be fixed on the hard disc bracket without the screwing means. Since the hard disc is combined with or disassembled from the hard disc bracket without the need of using a screwdriver or any other tool, the convenience of assembling or disassembling the hard disc is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A hard disc bracket for fixing a hard disc within a computer case, said hard disc bracket comprising:
a frame body;
at least one frame lateral plate located at a first side of said frame body for stopping said hard disc from being escaped from said frame body;
a receiving space for accommodating said hard disc, wherein said receiving space is defined by a bottom part of said frame body and said at least one frame lateral plate collaboratively; and
at least one hook located at an upper edge of said at least one frame lateral plate and extended from said upper edge of said at least one frame lateral plate in a direction toward said receiving space, wherein when said hard disc is accommodated within said receiving space, said hook is engaged with said hard disc to fix said hard disc on said frame body.

2. The hard disc bracket according to claim 1, wherein said hard disc bracket further comprises at least one protrusion, wherein said at least one protrusion is located at said first side of said frame body, said hard disc has at one perforation corresponding to said at least one protrusion, and said at least one perforation is disposed in a bottom surface of said hard disc and located at a side of said hard disc, wherein when said hard disc is accommodated within said receiving space, said at least one protrusion is inserted into said at one perforation, so that said hard disc is fixed within said receiving space.

3. The hard disc bracket according to claim 2, wherein said at least one protrusion is located at said first side of said frame body, and has a foolproof function, wherein when a front end of said hard disc faces a first end of said frame body, said hard disc is permitted to be accommodated within said receiving space, and said at least one protrusion is permitted to be aligned with said at least one perforation and inserted into said at least one perforation.

4. The hard disc bracket according to claim 2, wherein said at least one protrusion is extended from said bottom part of said frame body in a direction toward said receiving space, wherein said at least one protrusion is perpendicular to said bottom part of said frame body, and said at least one protrusion is integrally formed with said frame body.

5. The hard disc bracket according to claim 1, wherein said hard disc bracket further comprises a positioning wall, which is located at a first end of said frame body and connected with said at least one frame lateral plate, wherein said positioning wall has at least one positioning rib, which is disposed on an inner surface of said positioning wall, wherein when said hard disc is accommodated within said receiving space, said hard disc is stopped by said at least one positioning rib from being slid relative to the main frame.

6. The hard disc bracket according to claim 5, wherein said at least one positioning rib is extended from said positioning wall in a direction toward said receiving space, wherein said at least one positioning rib is integrally formed with said positioning wall, said positioning wall is perpendicular to said at least one frame lateral plate, and said positioning wall and said at least one frame lateral plate are integrally formed with said frame body.

7. The hard disc bracket according to claim 5, wherein said receiving space is defined by said bottom part of said frame body, said at least one frame lateral plate and said positioning wall collaboratively.

8. The hard disc bracket according to claim 1, wherein said hard disc bracket further comprises at least one stopper, which is located at a second end of said frame body and connected with said at least one frame lateral plate, wherein when said hard disc is accommodated within said receiving space, said hard disc is stopped by said stopper from being slid relative to said frame body.

9. The hard disc bracket according to claim 8, wherein said at least one stopper is perpendicular to said at least one frame lateral plate, said at least one stopper is integrally formed with said at least one frame lateral plate, and said at least one frame lateral plate is integrally formed with said frame body.

10. The hard disc bracket according to claim 1, wherein said computer case comprises:
an entrance/exit located at an end of said computer case, wherein said main frame of said hard disc bracket is permitted to be introduced into said computer case through said entrance/exit; and
a plurality of resilience sheets, which are located at bilateral sides of said computer case, wherein when said frame is stored within said computer case, said plurality of resilience sheets are sustained against said frame, thereby avoiding detachment of said frame from said computer case.
